(19) United States
(12) Patent Application Publication
(10) Pub. No.: US 2022/0123172 A1
(43) Pub. Date: Apr. 21, 2022

(54) OPTOELECTRONIC SEMICONDUCTOR DEVICE COMPRISING FIRST AND SECOND REGIONS OF A FIRST SEMICONDUCTOR LAYER AND METHOD FOR MANUFACTURING AN OPTOELECTRONIC SEMICONDUCTOR DEVICE

(71) Applicant: OSRAM Opto Semiconductors GmbH, Regensburg (DE)

(72) Inventor: Franz EBERHARD, Kilchberg (CH)

(21) Appl. No.: 17/427,921

(22) PCT Filed: Feb. 11, 2020
(86) PCT No.: PCT/EP2020/053467

§ 371 Date: Aug. 3, 2021

(30) Foreign Application Priority Data
Feb. 13, 2019 (DE) 10 2019 103 632.1

(51) Int. Cl. H01L 33/14; H01L 33/38

(52) U.S. Cl. CPC H01L 33/145; H01L 33/42; H01L 33/38

(57) ABSTRACT

An optoelectronic semiconductor device may include a first semiconductor layer of a first conductivity type and a second semiconductor layer of a second conductivity type. The first and second semiconductor layers may be part of a semiconductor layer stack. The optoelectronic semiconductor device may include an electrically conductive layer arranged over a surface of the first semiconductor layer facing away from the second semiconductor layer. The electrically conductive layer may be directly adjacent to first regions of the first semiconductor layer. The electrically conductive layer may be removed from second regions of the first semiconductor layer, or a dielectric material may be arranged between second regions of the first semiconductor layer and the current spreading layer. The smallest horizontal dimension of the second regions may be less than 2 μm.

### CROSS-REFERENCE TO RELATED APPLICATIONS

The present application is a national stage entry according to 35 U.S.C. § 371 of PCT Application No. PCT/EP2020/053467 filed on Feb. 11, 2020; which claims priority to German Patent Application Serial No. 10 2019 103 632.1 filed on Feb. 13, 2019; all of which are incorporated herein by reference in their entirety and for all purposes.

### TECHNICAL FIELD

The present invention relates to optoelectronic semiconductor devices having first and second regions of a first semiconductor layer.

### BACKGROUND

This patent application claims the priority of German patent application DE 10 2019 103 632.1, the disclosure contents of which are incorporated herein by reference.

A light emitting diode (LED) is a light emitting device based on semiconductor materials. For example, an LED includes a pn junction. When electrons and holes recombine with one another in the regions of the pn junction, due, for example, to a corresponding voltage being applied, electromagnetic radiation is generated.

In general, concepts are being researched by means of which a current supply to the semiconductor layers may be improved.

The objective is to provide an improved optoelectronic semiconductor device and an improved method for manufacturing an optoelectronic semiconductor device.

According to a non-limiting embodiment, the object is achieved by the subject matter and the method of the independent patent claims. Advantageous enhancements are defined in the dependent claims.

### SUMMARY

An optoelectronic semiconductor device comprises a first semiconductor layer of a first conductivity type and a second semiconductor layer of a second conductivity type, wherein the first and second semiconductor layers are part of a semiconductor layer stack. The optoelectronic semiconductor device furthermore comprises an electrically conductive layer which is arranged over a surface of the first semiconductor layer facing away from the second semiconductor layer. The electrically conductive layer is directly adjacent to first regions of the first semiconductor layer. The electrically conductive layer is removed from second regions of the first semiconductor layer, or a dielectric material is arranged between second regions of the first semiconductor layer and the electrically conductive layer. A smallest horizontal dimension of the second area is less than 2 pm.

According to further embodiments, an optoelectronic semiconductor device comprises a first semiconductor layer of a first conductivity type and a second semiconductor layer of a second conductivity type, wherein the first and the second semiconductor layer are part of a semiconductor layer stack. The optoelectronic semiconductor device furthermore comprises an electrically conductive layer which is arranged over a surface of the first semiconductor layer facing away from the second semiconductor layer, and a first contact structure which is electrically connected to the first semiconductor layer via the electrically conductive layer. The electrically conductive layer is directly adjacent to first regions of the first semiconductor layer. The electrically conductive layer is removed from second regions of the first semiconductor layer, or a dielectric material is arranged between second regions of the first semiconductor layer and the electrically conductive layer. A size of the first regions changes continuously at least in portions as the distance from the first contact structure increases.

The optoelectronic semiconductor device may furthermore comprise a first contact structure which is electrically connected to the first semiconductor layer via the electrically conductive layer.

The electrically conductive layer may, for example, be a current spreading layer. According to further embodiments, the electrically conductive layer may be a contact layer. For example, the electrically conductive layer may also be part of a current spreading structure.

According to further embodiments, an optoelectronic semiconductor device comprises a first semiconductor layer of a first conductivity type and a second semiconductor layer of a second conductivity type, wherein the first and the second semiconductor layer are part of a semiconductor layer stack. The optoelectronic semiconductor device further comprises an electrically conductive layer which is arranged over a surface of the first semiconductor layer facing away from the second semiconductor layer. The electrically conductive layer is connected to the first semiconductor layer in an electrically conductive manner and is directly adjacent to the first semiconductor layer in first and second regions. A contact resistivity between the electrically conductive layer and the first semiconductor layer is larger in the second regions than in the first regions.

For example, a smallest horizontal dimension of the second regions may be less than 2 μm.

The optoelectronic semiconductor device may furthermore comprise a first contact structure which is connected to the first semiconductor layer via the electrically conductive layer.

For example, a ratio of an area proportion of the second regions to an area proportion of the first regions may decrease as the distance from the first contact structure increases.

According to further embodiments, the optoelectronic semiconductor device may comprise a second contact element which is connected to the second semiconductor layer. A ratio of an area proportion of the second regions to an area proportion of the first regions may decrease as the distance from the second contact element increases.

The electrically conductive layer may, for example, be a contact layer or a current spreading layer. For example, the electrically conductive layer may also be part of a current spreading structure.

The second regions of the first semiconductor layer may overlap with an active zone for generating electromagnetic radiation.

For example, the second regions may each correspond to regions of the optoelectronic semiconductor device from which less electromagnetic radiation is emitted than from regions of the optoelectronic semiconductor device that correspond to first regions.

For example, the second regions may each be arranged in an edge region of the optoelectronic semiconductor device.

According to further embodiments, the second regions may correspond to a region of the optoelectronic semiconductor device having reduced optical outcoupling.

For example, the electrically conductive layer may comprise a transparent or a reflective or absorbent material.

According to embodiments, a dielectric material is arranged between second regions of the first semiconductor layer and the current spreading layer, and the dielectric material is part of a layer stack which further comprises a conductive layer.

A method for manufacturing an optoelectronic semiconductor device comprises forming a semiconductor layer stack which comprises a first semiconductor layer of a first conductivity type and a second semiconductor layer of a second conductivity type, and forming an electrically conductive layer over a surface facing away from the second semiconductor layer first semiconductor layer. The electrically conductive layer is formed such that it is directly adjacent to first regions of the first semiconductor layer. The electrically conductive layer is furthermore removed from second regions of the first semiconductor layer, or a dielectric material is arranged between second regions of the first semiconductor layer and the electrically conductive layer. The second regions have a smallest horizontal dimension of less than 2 μm.

According to further embodiments, a method for manufacturing an optoelectronic semiconductor device comprises forming a semiconductor layer stack which comprises a first semiconductor layer of a first conductivity type and a second semiconductor layer of a second conductivity type, forming an electrically conductive layer over a surface of the first semiconductor layer facing away from the second semiconductor layer, and forming a first contact structure which is electrically connected to the first semiconductor layer via the electrically conductive layer. The electrically conductive layer is formed such that it is directly adjacent to first regions of the first semiconductor layer. The electrically conductive layer is removed from second regions of the first semiconductor layer, or a dielectric material is arranged between second regions of the first semiconductor layer and the electrically conductive layer. A size of the second regions changes continuously at least in portions as the distance from the first contact structure increases.

According to further embodiments, a method for manufacturing an optoelectronic semiconductor device comprises forming a semiconductor layer stack which comprises a first semiconductor layer of a first conductivity type and a second semiconductor layer of a second conductivity type, and forming an electrically conductive layer over a surface of the first semiconductor layer facing away from the second semiconductor layer. The electrically conductive layer is connected to the first semiconductor layer in an electrically conductive manner and is directly adjacent to the first semiconductor layer in first and second regions. A contact resistivity between the electrically conductive layer and the first semiconductor layer is larger in the first regions than in the second regions.

For example, the smallest horizontal dimension of the second areas may be less than 2 μm.

For example, the method may comprise a treatment with high-energy ions. According to further embodiments, the contact resistivity between the electrically conductive layer and the first semiconductor layer in the second regions may be increased by local diffusion of hydrogen.

For example, the conductive layer may be reflective, and adjusting the contact resistivity may comprise applying different cover layer regions over the electrically conductive layer.

### BRIEF DESCRIPTION OF THE DRAWINGS

The accompanying drawings serve to provide an understanding of various embodiments. The drawings illustrate non-limiting embodiments and, together with the description, serve for explanation thereof. Further exemplary embodiments and many of the intended advantages will become apparent directly from the following detailed description. The elements and structures shown in the drawings are not necessarily shown to scale relative to each other. Like reference numerals refer to like or corresponding elements and structures.

FIG. 1A shows a cross-sectional view of an optoelectronic semiconductor device.

FIG. 1B shows a cross-sectional view of an optoelectronic semiconductor device in different planes.

FIG. 1C shows a vertical cross-sectional view of an optoelectronic semiconductor device.

FIG. 2A shows a cross-sectional view of a part of an optoelectronic semiconductor device in different sectional planes.

FIG. 2B shows a cross-sectional view of a part of an optoelectronic semiconductor device according to embodiments.

FIG. 2C shows a cross-sectional view of a part of an optoelectronic semiconductor device according to further embodiments.

FIG. 3A shows a horizontal cross-sectional view of an optoelectronic semiconductor device in different sectional planes.

FIG. 3B shows a vertical cross-sectional view of a part of an optoelectronic semiconductor device according to embodiments.

FIG. 4A shows a vertical cross-sectional view of an optoelectronic semiconductor device according to further embodiments.

FIG. 4B shows an enlarged view of a part of the optoelectronic semiconductor device.

FIG. 4C shows a horizontal cross-sectional view of an region of an optoelectronic semiconductor device according to embodiments.

FIG. 4D shows a horizontal cross-sectional view of a part of an optoelectronic semiconductor device according to further embodiments.

FIG. 4E shows a horizontal cross-sectional view of a part of an optoelectronic semiconductor device according to further embodiments.

FIG. 5A outlines a method according to embodiments.

FIG. 5B shows a vertical cross-sectional view of a workpiece during manufacturing an optoelectronic semiconductor device according to embodiments.

FIG. 5C shows a cross-sectional view of a part of an optoelectronic semiconductor device according to embodiments.

FIG. 6A shows a cross-sectional view of an optoelectronic semiconductor device according to further embodiments.

FIG. 6B shows a vertical cross-sectional view of an optoelectronic semiconductor device according to further embodiments.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since there are also other exemplary embodiments, and structural or logical changes may be made without departing from the scope as defined by the patent claims. In particular, elements of the exemplary embodiments described below may be combined with elements from others of the exemplary embodiments described, unless the context indicates otherwise.

The terms “wafer” or “semiconductor substrate” used in the following description may include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material or of an insulating material, for example sapphire. Further examples of materials for growth substrates include glass, silicon dioxide, quartz or a ceramic.

Depending on the intended use, the semiconductor may be based on a direct or an indirect semiconductor material. Examples of semiconductor materials particularly suitable for generating electromagnetic radiation include, without limitation, nitride semiconductor compounds, by means of which, for example, ultraviolet, blue or longer-wave light may be generated, such as GaN, InGaN, AlN, AlGaN, AlGaInN, AlGaInBN, phosphide semiconductor compounds by means of which, for example, green or longer-wave light may be generated, such as GaAsP, AlGaInP, GaP, AlGaP, and other semiconductor materials such as GaAs, AlGaAs, InGaAs, AlInGaAs, SiC, ZnSe, ZnO, Ga₂O₃, diamond, hexagonal BN and combinations of the materials mentioned. The stoichiometric ratio of the ternary compounds may vary. Other examples of semiconductor materials may include silicon, silicon germanium, and germanium. In the context of the present description, the term “semiconductor” also includes organic semiconductor materials.

The term “substrate” generally includes insulating, conductive or semiconductor substrates.

The terms “lateral” and “horizontal”, as used in the present description, are intended to describe an orientation or alignment which extends essentially parallel to a first surface of a semiconductor substrate or semiconductor body. This may be the surface of a wafer or a chip (die), for example.

The horizontal direction may, for example, be in a plane perpendicular to a direction of growth when layers are grown.

The term “vertical”, as used in this description, is intended to describe an orientation which is essentially perpendicular to the first surface of a substrate or semiconductor body. The vertical direction may correspond, for example, to a direction of growth when layers are grown.

To the extent used herein, the terms “have”, “include”, “comprise”, and the like are open-ended terms that indicate the presence of said elements or features, but do not exclude the presence of further elements or features. The indefinite articles and the definite articles include both the plural and the singular, unless the context clearly indicates otherwise.

In the context of this description, the term “electrically connected” means a low-ohmic electrical connection between the connected elements. The electrically connected elements need not necessarily be directly connected to one another. Further elements may be arranged between electrically connected elements.

The term “electrically connected” also encompasses tunnel contacts between the connected elements.

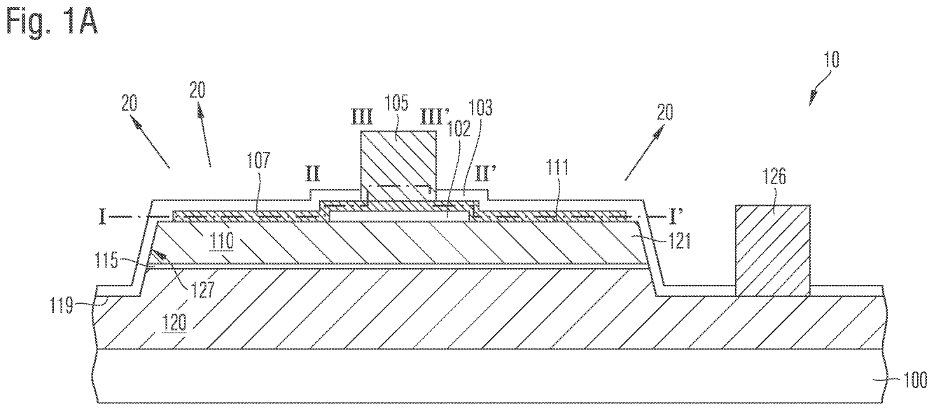

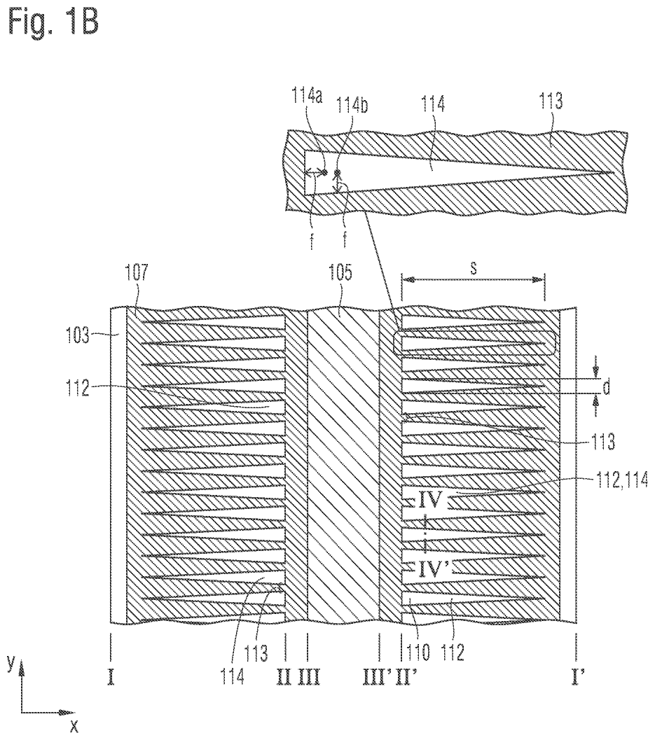

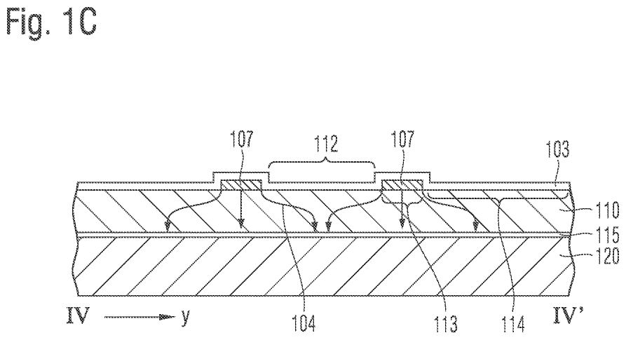

FIG. 1A shows a vertical cross-sectional view of an optoelectronic semiconductor device according to embodiments. The optoelectronic semiconductor device 10 shown in FIG. 1A may, for example, be a light emitting diode (LED). The optoelectronic semiconductor device 10 may, for example, be suitable for emitting electromagnetic radiation. According to further embodiments, the optoelectronic semiconductor device 10 may also be suitable for absorbing electromagnetic radiation.

A first semiconductor layer 110 and a second semiconductor layer 120 are arranged over a suitable carrier 100. For example, the first semiconductor layer 110 may be doped with dopants of a first conductivity type, for example p-type, and the second semiconductor layer 120 may be doped with dopants of a second conductivity type, for example n-type. For example, the first and the second semiconductor layers 110, 120 are based on a nitride compound semiconductor material. An active zone 115 may be arranged between the first semiconductor layer 110 and the second semiconductor layer 120.

The active zone may, for example, comprise a pn junction, a double heterostructure, a single quantum well structure (SQW, single quantum well) or a multiple quantum well structure (MQW, multi quantum well) for generating radiation. The term “quantum well structure” does not imply any particular meaning here with regard to the dimensionality of the quantization. Therefore it includes, among other things, quantum wells, quantum wires and quantum dots as well as any combination of these layers.

For example, the second semiconductor layer 120 may be arranged between the first semiconductor layer 110 and a suitable carrier 100. For example, the carrier 100 may be a growth substrate for the semiconductor layer sequence. Suitable materials for the carrier or the growth substrate may include, for example, sapphire, silicon carbide or gallium nitride.

The semiconductor layer stack may be patterned to form a mesa 121. Accordingly, a part of a first main surface 119 of the second semiconductor layer 120 may be exposed. A second electrical contact element 126 may, for example, contact the second semiconductor layer 120 in the region of an exposed first main surface 119. By applying a voltage between the first contact structure 105 and the second contact element 126, a current may be impressed into the optoelectronic semiconductor device. In general, the more uniform this current, the greater the brightness of the emitted electromagnetic radiation and thus the efficiency of the optoelectronic semiconductor device.

An electrically conductive layer or current spreading layer 107 is arranged over a first main surface 111 of the first semiconductor layer 110 facing away from the second semiconductor layer 120. According to embodiments, the current spreading layer 107 is connected to a first contact structure 105. For example, a dielectric layer 102 may be provided in a region of the first main surface where the current spreading layer 107 is in contact with the first contact structure 105. Usually, such a dielectric layer 102 may prevent an impressed electrical current from concentrating predominantly in that region of the first main surface 111 in which the first contact structure is directly adjacent to the current spreading layer 107. Such a dielectric layer 102 may effect a better overall distribution of the impressed current. According to embodiments, the dielectric layer 102 may also comprise a dielectric mirror layer. For example, a dielectric mirror layer may be formed by a sequence of very thin dielectric layers of different respective refractive indices. The dielectric mirror layer is thus, on the one hand, suitable for insulating components of the semiconductor device from one another. On the other hand, it is suitable for reflecting electromagnetic radiation.

The first contact structure 105 extends in a first horizontal direction, for example. For example, the first horizontal direction is perpendicular to the sectional plane shown. The first contact structure 105 may thus be formed in the shape of a line. According to embodiments, the electrically conductive or current spreading layer 107 may be directly adjacent to first regions 113 (not shown in FIG. 1A) of the semiconductor layer 110. Furthermore, the electrically conductive or current spreading layer 107 may be removed from second regions 114 of the semiconductor layer 11. Alternatively, a dielectric material 122 may be arranged between second regions 114 of the first semiconductor layer 110 and the current spreading layer 107. A smallest horizontal dimension of the second regions may be less than 2.0 μm or less than 1.5 μm or less than 1.0 μm. A distance between each position within the second region and a closest position in the first region may be less than 1.0 μm, for example.

A contact resistivity between the electrically conductive or current spreading layer 107 and the first semiconductor layer 110 may, for example, change locally along the first horizontal direction. For example, the contact resistivity may be relatively low in the first regions 113 and very high in the second regions 114. Due to the finite resistance of the first semiconductor layer and the charge carrier diffusion, a local equalization of the charge carrier concentrations occurs. As a result, given a corresponding size of the region exhibiting locally varying contact resistivity, an averaged resistance value results, which is also referred to hereinafter as “local supply line resistance” or “local input line resistance”.

FIG. 1B shows a horizontal cross-sectional view of the optoelectronic semiconductor device. This cross-sectional view is taken along different sectional planes, as illustrated, for example, in FIG. 1A. For example, one cross-sectional view is taken through the current spreading layer 107 between I and II. Between II and III, the sectional plane is slightly raised and follows the course of the current spreading layer 107. Between III and III′, the cross-sectional view intersects the first contact element 105. This is followed by another section through the current spreading layer 107 in different planes. The first contact structure 105 extends along the y direction.

As shown in FIG. 1B, the conductive material of the current spreading layer 107 is locally recessed. A plurality of recesses 112 is arranged in the current spreading layer 107. A maximum width d of the recesses, measured in the y direction, may be, for example, less than 2 μm, or, for example, less than 1.5 μm or less than 1 μm. Furthermore, a distance f between each position 114a, 114b within the second region 114 and a closest position of the first region 113 may be less than 1 μm, for example less than 0.75 μm or less than 0.5 μm. According to further embodiments, the maximum width d of the recesses, as measured in the y direction, may be greater than 2 μm. According to further embodiments, the distance f may be greater than 2 μm.

A length s of the recesses 112, as measured in the x direction, may be approximately 100 to 200 μm. The recesses 112 may, for example, have the shape of triangles, for example isosceles triangles, with a short base corresponding to width d and two long legs. A plurality of recesses 112 formed in this manner is arranged adjacent to one another along the y direction. Furthermore, such a shape of the recess allows for the averaged contact resistivity or local input line resistance to decrease along the x direction. For example, the averaged contact resistivity or local input line resistance may decrease continuously, at least in portions. For example, “continuously” in this context may mean that the local input line resistance does not change abruptly, but gradually. For example, the local input line resistance may decrease in an approximately linear manner as the distance from the first contact structure 105 increases. According to further embodiments, the local input line resistance may not change, not even in portion. In this case, the contact resistance in a region in the vicinity of or on the side of the first contact structure 105 is greater than in a region facing away from the first contact structure 105. For example, a material of the current spreading layer 107 may be a conductive metal oxide, for example ITO or IZO (indium zinc oxide). Since the first semiconductor layer may have very low electrical conductivity, a locally uniform charge carrier distribution may be achieved at a structure size of the recesses as discussed above.

As further illustrated in FIG. 1B, the second regions 114 may extend in a direction leading away from the first contact structure 105. If the first contact structure 105 extends, for example, in the y direction, the second regions 114 extend in the x direction. Along the y direction, i.e., in a direction perpendicular to the direction of extension of the second regions 114, first and second regions 113, 114 are each arranged alternately.

FIG. 1C shows a cross-sectional view along the y direction which may be taken, for example, between IV and IV′ as shown in FIG. 1B. As may be seen, recesses 112 are arranged between webs of the current spreading layer 107. Correspondingly, a current path 104 is formed as shown in FIG. 1C. The current is thus not impressed over the entire surface of the first semiconductor layer 110 but only over those surface regions in which parts of the current spreading layer 107 are directly adjacent to the first semiconductor layer 110.

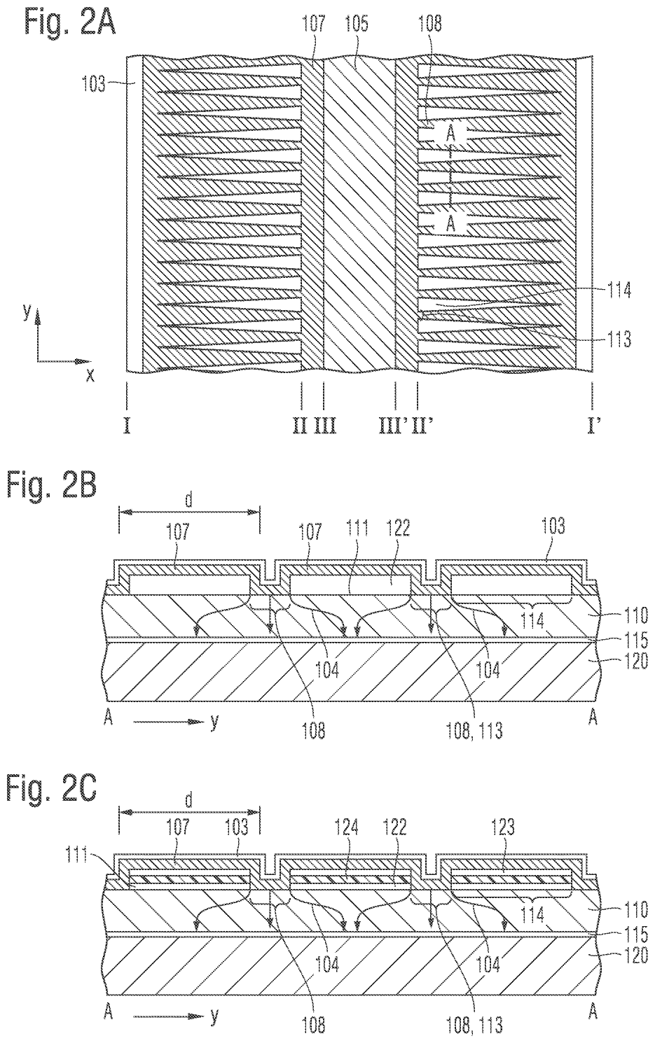

FIGS. 2A to 2C show views of optoelectronic semiconductor devices according to further embodiments, in which, instead of the recesses 112, an insulating material is formed locally adjacent to the first semiconductor layer 110. In this case, the current spreading layer 107 may be formed as a continuous layer, for example. According to these embodiments, a dielectric material 122 may thus be arranged between second regions 114 of the first semiconductor layer 110 and the current spreading layer 107. A smallest horizontal dimension of the second regions is less than 2.0 μm. In this case, too, a distance between each position 114a, 114b (shown in FIG. 1B) within the second region 114 and a closest position of the first region 113 may be less than 1.0 μm or less than 0.5 μm, for example. According to further embodiments, a size of the first regions 113 may change continuously in a direction perpendicular to the first horizontal direction.

FIG. 2A again shows a cross-sectional view of a part of the optoelectronic semiconductor device in different sectional planes, in analogy to the illustration of FIG. 1B.

FIG. 2B shows a cross-sectional view through a part of the semiconductor layer stack between A and A with the current spreading layer 107 applied, as indicated in FIG. 2A. As shown in FIG. 2B, a first dielectric layer 122 is applied and patterned over the first semiconductor layer 110. For example, the first dielectric layer 122 is patterned such that it is present in second regions 114. For example, the first dielectric layer 122 may contain silicon oxide, aluminum oxide, or some other dielectric material. A layer thickness of the dielectric layer 122 may, for example, be 20 to 70 nm, for example 30 to 40 nm. The first dielectric layer 122 is patterned to form portions as shown in FIG. 2B. The width d of the portions decreases in the x direction as the distance from the first contact structure 105 increases. A current spreading layer 107 is conformally applied over the patterned portions of the first dielectric layer 122. In addition, a passivation layer 103 may be applied over the current spreading layer 107. The passivation layer may contain silicon oxide or some other transparent dielectric material, for example.

Due to the presence of the patterned first dielectric layer 122, the current spreading layer 107 is directly adjacent to the first semiconductor layer 110 only at the contact regions 108 or first regions 113. In the intermediate regions or second regions 114, no electrical contact occurs between the current spreading layer 107 and the first semiconductor layer 110. As a result, the contact resistance between the current spreading layer and the first semiconductor layer is increased. The current path accordingly assumes the course shown in FIG. 2B.

According to further embodiments, as illustrated in FIG. 2C, instead of a single dielectric layer, a layer stack of dielectric and, if desired, conductive layers may be arranged between regions of the current spreading layer 107 and the first semiconductor layer 110. According to the embodiments illustrated in FIG. 2C, for example, a layer stack which includes a first dielectric layer 122, a conductive layer 124, and a second dielectric layer 123 may be formed and patterned locally over regions of the first semiconductor layer 110. According to further embodiments, the second dielectric layer 123 may be omitted. The current spreading layer 107 may then be formed. For example, the conductive layer 124 may be electrically connected to the current spreading layer 107. For example, the first and second dielectric layers 122, 123 may each contain silicon oxide. The conductive layer 124 may, for example, contain a conductive metal oxide, for example ITO. For example, the conductive layer 124 may be formed from the same material as the current spreading layer 107. The first dielectric layer may, for example, have a layer thickness of 30 to 70, for example 40 to 60 nm. The conductive layer 124 may, for example, have a layer thickness between 10 and 50 nm. The second dielectric layer 123 may, for example, have a layer thickness between 40 and 100 nm, for example 60 to 80 nm. The layer stack of the first dielectric layer 122, the conductive layer 124 and optionally the second dielectric layer 123 may be patterned along the x and y directions in a manner similar to that described with reference to FIGS. 2A and 2B. Correspondingly, the current spreading layer 107 may be deposited as a coherent layer and may be directly adjacent to the first semiconductor layer only in the contact regions 108. In this way, a current path 104 may take the course illustrated in FIG. 2C.

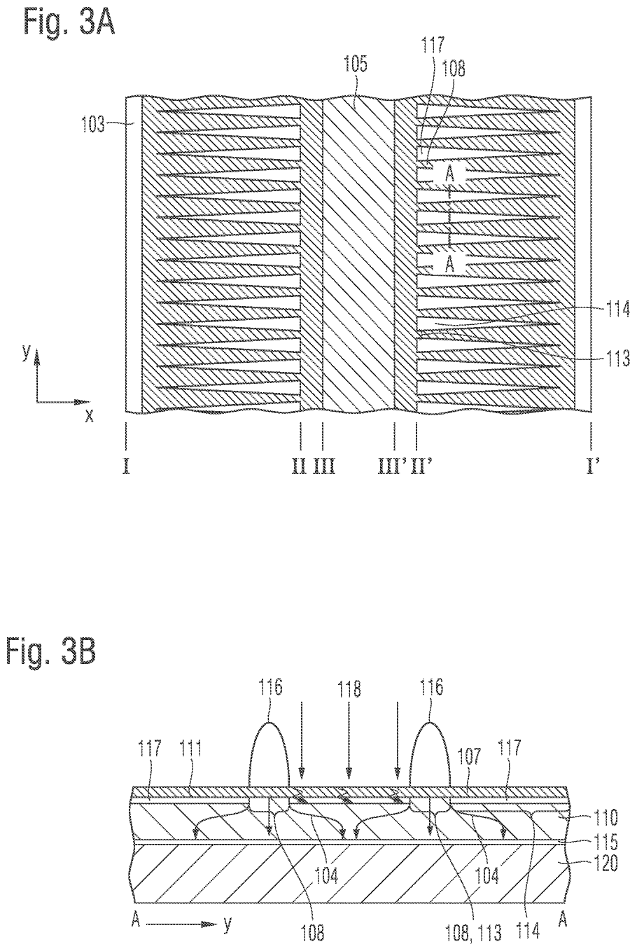

FIGS. 3A and 3B illustrate an optoelectronic semiconductor device according to further embodiments. As will be described, the contact resistance may be changed due to local damage to the electrical contact between the semiconductor layer and the electrically conductive layer.

FIG. 3A shows a schematic cross-sectional view of a part of an optoelectronic semiconductor device. This cross-sectional view is taken in analogy to the cross-sectional view of FIGS. 1B and 2A.

FIG. 3B shows a vertical cross-sectional view along the y direction, for example between A and A as shown in FIG. 3A. A current spreading layer 107 is formed over the entire surface area of the first main surface 111 of the first semiconductor layer 110. A mask 116 is placed over first regions 113 of the surface of the current spreading layer 107. Between adjacent mask portions, a region above the current spreading layer 107 is not covered with mask material. This region corresponds to the second regions 114 in each case. A treatment with energy-rich ions, for example hydrogen, oxygen or fluorine ions, is then carried out. An ion bombardment process 118 may be performed under similar conditions and parameters as a reactive ion etching process. As a result of the bombardment with the high-energy ions, the interface between the first semiconductor layer 110 and the current spreading layer 107 is modified, leading to an increased contact resistance. As a result, locally damaged regions 117 are formed. The locally damaged regions 117 are arranged adjacent to the second regions 114 of the first semiconductor layer 110 and overlap them.

The mask may, for example, be formed triangular in a horizontal plane. As a result, the extension of the damaged regions 117 may be configured as shown in FIG. 3A along the x and y directions. According to these embodiments, a contact region between the first semiconductor layer 110 and the current spreading layer 107 is modified locally, so that a different contact resistivity is obtained in each case. In doing so, the size of the damaged regions and thus the local input line resistance changes continuously along the x direction. According to these embodiments, a local input line resistance between the current spreading layer 107 and the first semiconductor layer is greater in the second regions 114 than in the first regions.

For example, a smallest horizontal dimension of the second regions is less than 2.0 μm.

As described above, an optoelectronic semiconductor device 10 thus comprises a first semiconductor layer 110 of a first conductivity type and a second semiconductor layer 120 of a second conductivity type. The first and second semiconductor layers 110, 120 are parts of a semiconductor layer stack. The optoelectronic semiconductor device furthermore includes a current spreading layer 107 which is arranged over a surface 111 of the first semiconductor layer 110 facing away from the second semiconductor layer 120. According to embodiments, the optoelectronic semiconductor device further comprises a first contact structure 105, which is electrically connected to the first semiconductor layer 110 via the current spreading layer 107. The first contact structure may extend, for example, along a first horizontal direction. A local input line resistance between the current spreading layer 107 and the first semiconductor layer 110 changes continuously, at least in portions, as the distance from the contact structure increases.

The concept described with reference to FIGS. 3A and 3B may also be extended to further optoelectronic semiconductor devices. For example, this concept may also be applied to semiconductor devices in which a material of the current spreading layer is absorbent or reflective.

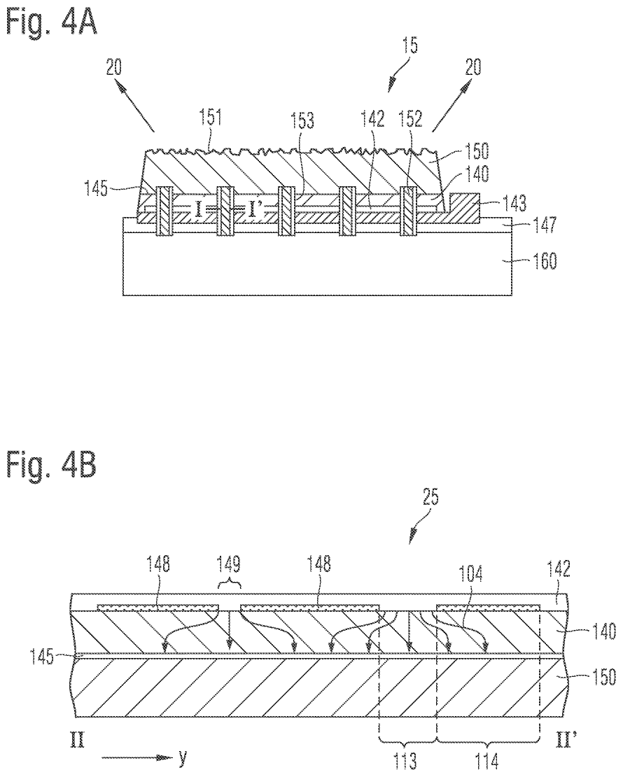

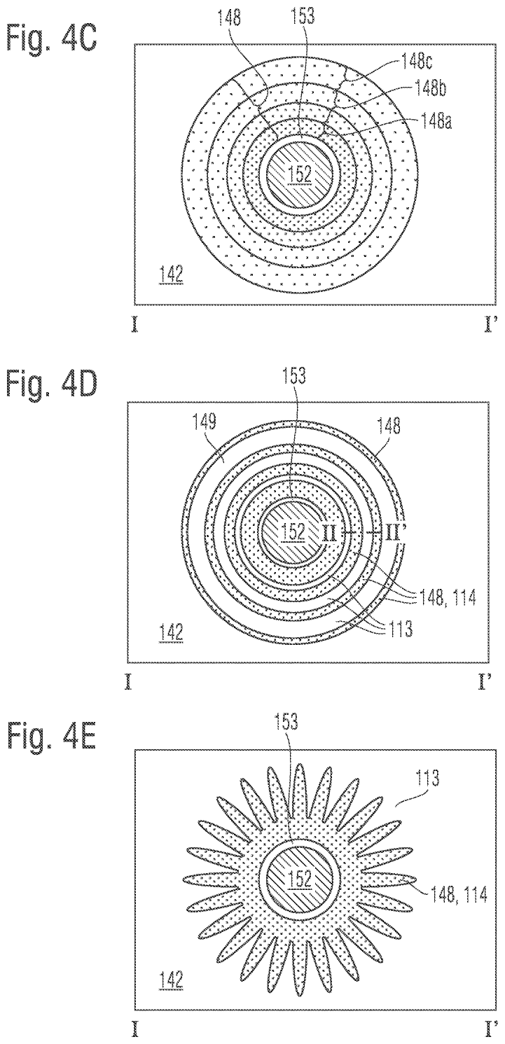

FIG. 4A shows a cross-sectional view through a part of an optoelectronic semiconductor device 15 according to further embodiments. The optoelectronic semiconductor device 15 comprises a semiconductor layer stack composed of a first semiconductor layer 140 of a first conductivity type, for example p-type, and a second semiconductor layer 150 of a second conductivity type, for example n-type. An active zone 145 is arranged between the first semiconductor layer 140 and the second semiconductor layer 150. A first contact layer 142 is arranged adjacent to the first semiconductor layer 140. For example, the contact layer 142 may include a reflective material, such as silver. A first current spreading layer 143 is arranged on the side of the first semiconductor layer 140. The first current spreading layer 143 may be connected to the first semiconductor layer 140 via the contact layer 142, for example. Electromagnetic radiation emitted by the optoelectronic semiconductor device 15 may be emitted via a second main surface 151 of the second semiconductor layer 150, for example.

The optoelectronic semiconductor device is applied onto a carrier 160. For example, the carrier 160 may be composed of a semiconductor material, for example silicon or germanium, or of a metal. The semiconductor layer stack is applied onto the carrier 160 such that the first semiconductor layer 140 is arranged between the second semiconductor layer 150 and the carrier 160. For example, an insulating material 147 may be arranged between the first current spreading layer 143 and the electrically conductive carrier 160. A plurality of second contact elements 152 may extend through the first semiconductor layer 140 and through the active zone 145. An electrical contact between the conductive carrier 160 and the second semiconductor layer 150 may be established by the second contact elements 152. The electrically conductive carrier 160 thus acts as a second current spreading layer. The second contact elements 152 may each be insulated from the adjacent semiconductor material and the first current spreading layer 143, and from the first contact layer 142 via a side wall insulation 153. A material of the first current spreading layer 143 may also comprise an absorbent or reflective material. The first and second semiconductor layers 140, 150 may contain GaN, for example.

FIG. 4B shows an example of an enlarged cross-sectional view between II and II′ as indicated in FIG. 4D. As shown in FIG. 4B, a contact region between the first contact layer 142 and second regions 114 of the first semiconductor layer 140 is modified locally. More precisely, modified contact regions 148 are arranged in portions between second regions 114 of the first semiconductor layer 140 and the first contact layer 142. Unmodified contact regions 149 are arranged between adjacent modified contact regions 148 and correspond to the first regions 113 of the first semiconductor layer 140. A current path 104 from the first contact layer 142 to the first semiconductor layer 140 and to the active zone 145 is shaped as shown in FIG. 4B. Therefore no uniform power supply occurs, but rather the power supply is adjusted, for example, via the size of the non-modified contact regions.

FIG. 4C shows a horizontal enlarged cross-sectional view of a part of the optoelectronic semiconductor device between I and I′, as illustrated in FIG. 4A. A modified contact region 148 is formed around a second contact element 152. In this manner, the current impression from the first contact layer 142 to the first semiconductor layer 140 is reduced in a region which is directly adjacent to the second contact element 152. The modified contact region 148 is therefore located in a region of the optoelectronic semiconductor device in which a current is impressed via the second contact element 152 into the second semiconductor layer 150 and thus into the active zone 145.

For example, the modified contact region 148 may have different sub-regions which are each arranged concentrically around the second contact element 152. For example, a first contact region 148a may be arranged immediately adjacent to the second contact element 152 and insulated therefrom by the side wall insulation 153. The first sub-region 148a may be followed by further sub-region 148b, 148c, each of which is located at a greater distance from the second contact element 152. Both first and second regions 113, 114 of the first semiconductor layer may be present in each of the sub-regions 148a, 148b, 148c. An extent to which the contact between the first semiconductor layer 140 and the first contact layer 142 is modified may decrease as the distance from second contact element 152 increases. Accordingly, the local input line resistance decreases as the distance from the second contact element 152 increases. A different extent of the modification of the contact region may be set by different surface proportions of the first and second regions 113, 114. For example, an area coverage of the second regions 114 or of the modified contact regions in the first sub-region 148a may be greater than in the second sub-region 148b, and the area coverage of the second regions 114 or of the modified contact regions is greater in the second sub-region 148b than in the third sub-region 148c. For example, the first regions 113 in the first sub-region 148a have a significantly smaller lateral extent than in the third sub-region 148c.

FIG. 4D shows a horizontal cross-sectional view through a region around a second contact element 152 according to further configurations. The cross-sectional view is taken between I and I′, as illustrated, for example, in FIG. 4A. As illustrated in FIG. 4D, a modified contact region 148 may each be arranged in a ring around a second contact element 152. The modified contact region 148 is thus located in a region of the optoelectronic semiconductor device in which a current is impressed via the second contact element 152 into the second semiconductor layer 150 and thus into the active zone 145.

Unmodified contact regions 149, each of which corresponds to the first regions 113 of the first semiconductor layer 140, may each be arranged in a ring-shaped and concentric manner between modified contact regions. According to embodiments, the first regions 113 may not be present in each of the modified contact regions 148. For example, a maximum ring width of the modified contact regions 148 in the lateral direction may be 2 μm or 1 μm. The modified contact regions 148 each correspond to the second regions 114 of the first semiconductor layer. The width of the individual rings may vary in each case. For example, a ring width of the modified contact regions 148 and thus the area coverage of the second regions 114 of the first semiconductor layer may decrease as the distance from the second contact element 152 increases. According to further embodiments, the ring width of the unmodified contact regions 149 and thus the area coverage of the first contact regions 113 may increase as the distance from the second contact element 152 increases. As a result, a degree of current impression in the first semiconductor layer 140 may be adapted accordingly. For example, a minimum dimension of the second regions 114 may be less than 2 μm. For example, a distance between each position within the second region 114 and a closest position of the first region 113 may be less than 1 μm or less than 0.5 μm.

FIG. 4E shows a configuration of the modified contact region 148 according to further embodiments. The horizontal cross-sectional view of FIG. 4E is again taken between I and I′, as illustrated in FIG. 4A. As a result of the specific configuration of the modified contact region 148, an area coverage of the modified contact region 148 and thus of the second region 114 of the semiconductor layer 140 decreases as the distance from the second contact element 152 increases. Correspondingly, the local input line resistance also decreases as the distance from the second contact element 152 increases.

As further illustrated in FIG. 4E, the second regions 114 may extend in a direction leading radially outward away from the second contact element 152. First and second regions 113, 114 are each arranged alternately perpendicular to an extension direction of the second regions 114.

As has been described, according to embodiments, the local input line resistance and thus the current impression in the active zone may be controlled in a targeted manner by spatially varying the contact resistivity between the current spreading layer and the first semiconductor layer. In this manner, the current impression may be reduced at those locations where a large amount of radiation would be generated, for example, due to the proximity to the second contact element 152. As a result, a more homogeneous generation of the electromagnetic radiation and thus greater brightness and therefore better efficiency may be effected.

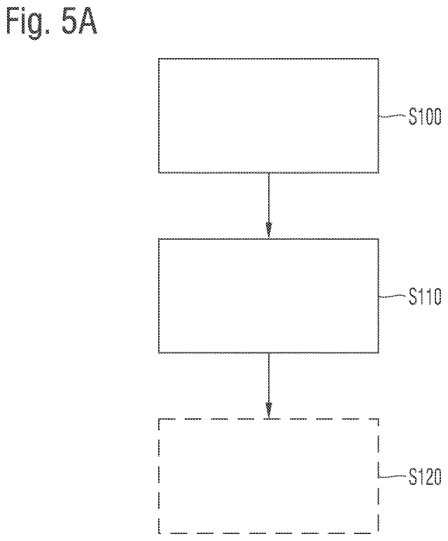

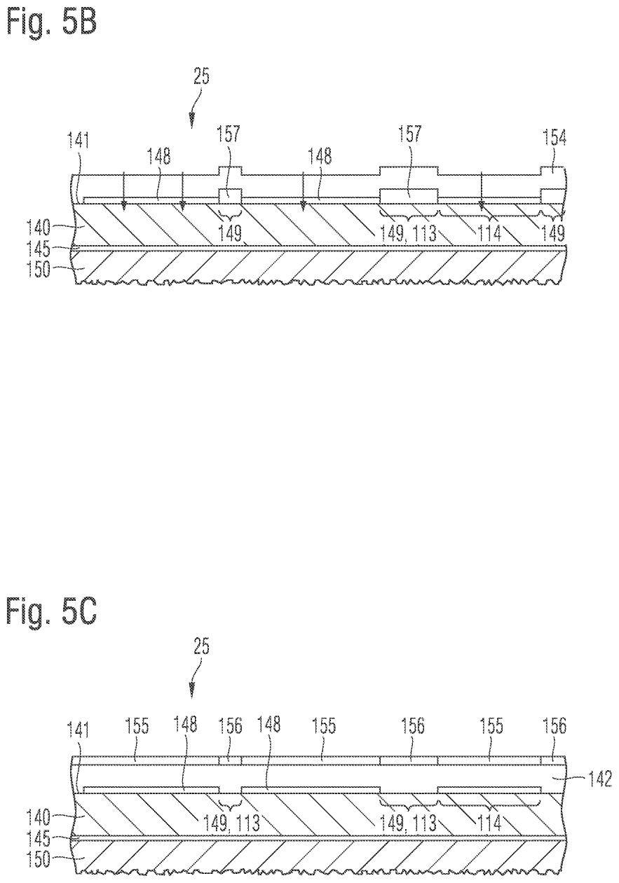

FIG. 5A illustrates a method according to embodiments. A method for manufacturing an optoelectronic semiconductor device comprises forming (S100) a semiconductor layer stack, which comprises a first semiconductor layer of a first conductivity type and a second semiconductor layer of a second conductivity type, and forming (S110) an electrically conductive or current spreading layer over a surface of the first semiconductor layer facing away from the second semiconductor layer. The electrically conductive or current spreading layer is formed such that it is directly adjacent to first regions of the first semiconductor layer. Furthermore, the current spreading layer is removed from second regions of the first semiconductor layer, or a dielectric material is arranged between second regions of the first semiconductor layer and the current spreading layer. A distance between each position within the second region and a closest position in the first region is less than 1 μm, for example.

According to further embodiments, the method comprises forming (S120) a first contact structure which is electrically connected to the first semiconductor layer via the current spreading layer. For example, a size of the second regions may change continuously, at least in portions, as the distance from the first contact structure increases.

According to further embodiments, a contact resistivity between the electrically conductive layer and the first semiconductor layer may be greater in the second regions than in the first regions.

According to embodiments, a conductive layer which is in electrical contact with the first semiconductor layer may contain a reflective or absorbent material. For example, a contact resistance between the electrically conductive layer and the first semiconductor layer may change depending on a position along a horizontal direction. For example, the electrically conductive layer may be a first contact layer and/or a first current spreading layer.

FIG. 5B shows a cross-sectional view through a part of a workpiece 25 in the course of performing a method according to embodiments. The structure shown in FIG. 5B illustrates, for example, the manufacture of the modified contact regions 148 shown in FIG. 4B and of the unmodified contact regions 149. A barrier layer 157 is applied over a first main surface 141 of the first semiconductor layer 140 and patterned. The barrier layer 157 is patterned such that it covers first regions 113 and does not cover second regions 114 of the first semiconductor layer 140. It thus covers those surface regions which should not be modified, and thus acts as a mask. According to embodiments, a hydrogen-containing layer 154 is deposited over the resulting surface. For example, this may be a hydrogen-containing silicon nitride layer. As a result of the deposition of the hydrogen-containing layer 154, the second regions 114 of the first semiconductor layer 110 are deactivated by hydrogen. As a result, the contact between the first semiconductor layer 140 and a first contact layer 142 applied subsequently is locally modified or deteriorated. No modification takes place in the first regions 113 which are covered by the barrier layer 157. Using this method, the first semiconductor layer 140 (e.g., p-GaN) is selectively made electrically “bad”. After the hydrogen-containing layer 154 and the barrier layer have been removed, a contact layer 142 is applied over the entire surface area. As a result, the modified contact regions 148 shown in FIG. 4B and the unmodified contact regions 149 emerge. Alternatively, such modified contact regions 148 may also be produced by treatment in a hydrogen atmosphere. According to further embodiments, the material of the first semiconductor layer 140 may also be damaged locally, for example by implantation, for example ion implantation.

According to further embodiments, it is possible to adjust the contact resistivity between the first contact layer 142 and the first semiconductor layer locally by means of different cover layer materials 155, 156 over the first contact layer 142. As illustrated in FIG. 5C, a first contact layer 142 is applied over the entire surface area of the first main surface 141 of the first semiconductor layer. Then a cover layer is applied which comprises first cover layer regions 155 and second cover layer regions 156, each of different materials. For example, the first cover layer regions 155 may be applied over the second region 114 and the second cover layer regions 156 over the first regions 113 of the first semiconductor layer 140. By using the different materials of the cover layer, a contact resistivity differing from that of the underlying semiconductor material is set in each case. According to one explanation, material diffuses from the various cover layer regions, for example through the first contact layer 142, and may thereby locally change the contact resistance. By using a different number of openings or openings of different sizes, a different surface proportion of the modified contact may be provided in each case. In this manner, the local input line resistance to the active zone 145 may be varied locally.

As has been described, the contact resistivity between the conductive layer and the first semiconductor layer may be modified locally in order to achieve a more uniform impression of the current. According to further embodiments, it is possible, using the concepts described, to control the impression of the current in a targeted manner to take place in specific regions of the optoelectronic semiconductor device. In this manner, for example, current impression in regions in which shadowing occurs or in which non-radiative recombination may occur may be suppressed.

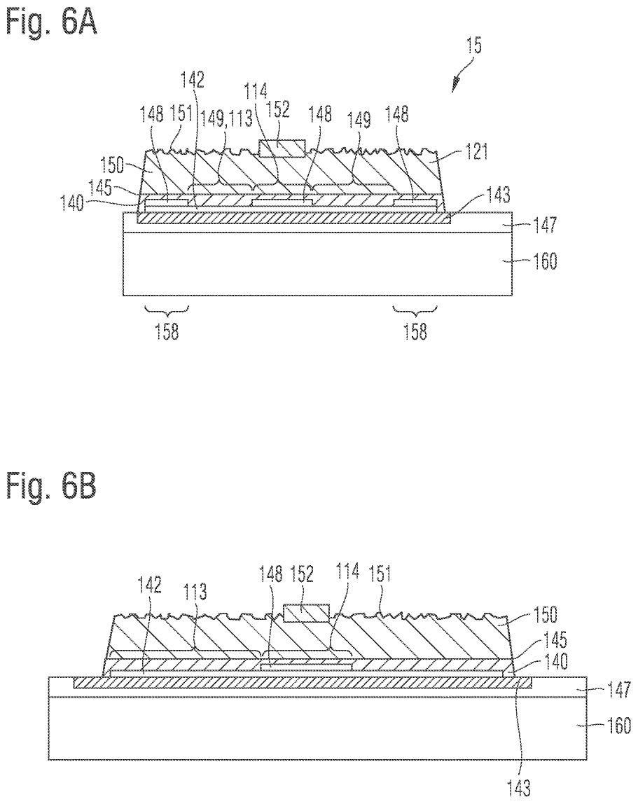

FIG. 6A shows a schematic cross-sectional view of an optoelectronic semiconductor device 15, in which the first semiconductor layer 140 is arranged between a second semiconductor layer 150 and a carrier 160. A first current spreading layer 143 and a first contact layer 142 are connected to the first semiconductor layer 140 in an electrically conductive manner. The conductive layers 142, 143 adjacent to the first semiconductor layer 140 may be reflective or absorbent. For example, the contact layer 142 may be a reflective silver layer. The semiconductor layers may be patterned to form a mesa, for example.

A second contact element 152 is arranged in the region of the first main surface 151 of the second semiconductor layer 150. By using such an arrangement of second contact elements, the emitted electromagnetic radiation may be shaded, for example, in a central region of the optoelectronic semiconductor device 15. By arranging a modified surface region 148 in the central region, less current is impressed there, thereby reducing optical losses. Furthermore, more non-radiative recombination may occur in an edge region 158 of the mesa 121 due to open bonds (“dangling bonds”). By providing the modified contact regions 148, current impression may now be controlled in a targeted manner, so that less current is impressed in the edge region 158 and thus non-radiative recombination is suppressed or reduced.

FIG. 6B shows an optoelectronic semiconductor device according to further embodiments. In this case, too, the second contact element 152 is arranged in the region of the first main surface 151 of the second semiconductor layer 150. For example, the contact element 152 may have a lateral extension of approximately 100 μm. By having a modified contact region 148 overlap with the second contact element 152 in the vertical direction, less current impression takes place at this location. This may be achieved, for example, by using one of the above methods for modifying the electrical contact between the first semiconductor layer 140 and the first contact layer 142, for example a method in which different cover layer regions are applied over the semiconductor layer stack. According to further embodiments, silicon nitride or another dielectric material may be applied locally between the first semiconductor layer 140 and the first contact layer 142.

As has been described, current impression may be controlled by a local change in the contact resistivity between a contact layer and the first semiconductor layer.

For example, in the case of a transparent contact layer, this may be done by locally removing parts of the transparent contact layer in second regions of the first semiconductor layer or by underlaying them with a dielectric material. For example, the second regions may have a maximum lateral dimension of 2.0 μm or 1.5 μm or 1.0 μm in a first direction. For example, a lateral dimension may continuously decrease in a direction perpendicular to the first direction. At such a dimension, a local equalization of the charge carrier concentrations may occur as a result of the finite resistance of the first semiconductor layer and of the charge carrier diffusion. As a result, a uniform current impression takes place.

In the case of a reflective or absorbent contact or current spreading layer, parts of the contact layer or the current spreading layer may be underlaid with a dielectric material. Furthermore, diffusion of hydrogen or other atoms may occur, through which the contact resistivity is locally changed.

According to further embodiments, the contact between the first semiconductor layer and a conductive layer which is connected to the first semiconductor layer may be locally damaged, activated or deactivated in order to control current impression.

In particular, by the measures described, current impression in predetermined semiconductor regions that are directly adjacent to the active zone is reduced. As a result, emission in these predetermined regions may be suppressed. In this manner, electrical and optical losses may be minimized. Furthermore, improved efficiency of the generation of electromagnetic radiation is achieved.

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is to be limited by the claims and their equivalents only.

### LIST OF REFERENCES

10 optoelectronic semiconductor device
15 optoelectronic semiconductor device
20 emitted electromagnetic radiation
25 workpiece
100 carrier
102 dielectric layer
103 passivation layer
104 current path
105 first contact structure
107 current spreading layer
108 contact region
110 first semiconductor layer
111 first main surface of the first semiconductor layer
112 recess
113 first region of the first semiconductor layer
114 second region of the first semiconductor layer
114a,b positions within the second region
115 active zone
116 mask
117 damaged region
118 ions
120 second semiconductor layer
121 mesa
122 first dielectric layer
123 second dielectric layer
124 conductive layer
125 second contact structure
126 second contact element
127 sidewall of the mesa
140 first semiconductor layer
141 first main surface of the first semiconductor layer
142 first contact layer
143 first current spreading layer
145 active zone
147 insulating material
148 modified contact region
148a first sub-region
148b second sub-region
148c third sub-region
149 unmodified contact region
150 second semiconductor layer
151 first main surface of the second semiconductor layer
152 second contact element
153 sidewall insulation
154 hydrogen-containing layer
155 first cover layer region
156 second cover layer region
157 barrier layer
158 edge region
160 carrier

1. (canceled)

2. An optoelectronic semiconductor device comprising:
a first semiconductor layer of a first conductivity type;
a second semiconductor layer of a second conductivity type, wherein the first and second semiconductor layers are part of a semiconductor layer stack;
an electrically conductive layer arranged over a surface of the first semiconductor layer facing away from the second semiconductor layer; and
a first contact structure electrically connected to the first semiconductor layer via the electrically conductive layer;
wherein the electrically conductive layer is directly adjacent to first regions of the first semiconductor layer;
wherein the electrically conductive layer is removed from second regions of the first semiconductor layer;
a size of the first regions changes continuously at least in portions as the distance from the first contact structure increases; and
the second regions each correspond to regions of the optoelectronic semiconductor device from which less electromagnetic radiation is emitted than from regions of the optoelectronic semiconductor device corresponding to first regions.

3-5. (canceled)

6. The optoelectronic semiconductor device according to claim 2, wherein a ratio of an area proportion of the second regions to an area proportion of the first regions decreases as the distance from the first contact structure increases.

7-8. (canceled)

9. The optoelectronic semiconductor device according to claim 2, wherein the second regions of the first semiconductor layer overlap with an active zone for generating electromagnetic radiation.

10. The optoelectronic semiconductor device according to claim 2, wherein the first and the second semiconductor layers are patterned to form a mesa and the second regions are each arranged in an edge region of the mesa.

11. The optoelectronic semiconductor device according to claim 2, wherein the second regions correspond to a region of the optoelectronic semiconductor device having reduced optical outcoupling.

12. The optoelectronic semiconductor device according to claim 2, wherein the electrically conductive layer comprises a transparent material and implements a current spreading layer.

13. The optoelectronic semiconductor device according to claim 2, wherein the electrically conductive layer comprises a reflective or absorbent material.

14-15. (canceled)

16. A method for manufacturing an optoelectronic semiconductor device comprising:
forming a semiconductor layer stack comprising a first semiconductor layer of a first conductivity type and a second semiconductor layer of a second conductivity type;
forming an electrically conductive layer over a surface of the first semiconductor layer facing away from the second semiconductor layer;
forming a first contact structure electrically connected to the first semiconductor layer via the electrically conductive layer;
wherein the electrically conductive layer is formed such that it is directly adjacent to first regions of the first semiconductor layer;
wherein the electrically conductive layer is removed from second regions of the first semiconductor layer;
a size of the second regions changes continuously at least in portions as the distance from the first contact structure increases; and
the second regions each correspond to regions of the optoelectronic semiconductor device from which less electromagnetic radiation is emitted than from regions of the optoelectronic semiconductor device corresponding to first regions.

17. (canceled)

18. The method according to claim 16, wherein a smallest horizontal dimension of the second regions is less than 2 μm.

19-21. (canceled)
